(19) United States
(12) Patent Application Publication
(10) Pub. No.: US 2009/0124067 A1
(43) Pub. Date: May 14, 2009

(54) METHOD TO DECREASE THIN FILM TENSILE STRESSES RESULTING FROM PHYSICAL VAPOR DEPOSITION

(75) Inventors: Andrew N. Contes, Chandler, AZ (US); Eric J. Li, Chandler, AZ (US); Arturo Urquiza, Gilbert, AZ (US)

Correspondence Address: COOL PATENT, P.C.;c/o CPA Global, P.O. BOX 52050, MINNEAPOLIS, MN, 55402, US

(73) Assignee: Intel Corporation

(21) Appl. No.: 11/940,220

(22) Filed: Nov. 14, 2007

(51) Int. Cl. H01L 21/20

(52) U.S. Cl. 438/503; 257/E21.09

(57) ABSTRACT

A method and apparatus for a backside metallization of a wafer is provided. The wafer comprised of a first substance is bent by creating tension on a backside and creating compression on a front side prior to deposition of a thin film of a second substance. After deposition, the wafer is released and the thin film deposited on the wafer exhibits less tensile stress than if the thin film was deposited on a flat wafer.

### BACKGROUND

Backside metallization (BSM) deposition is a process of applying a thin film of atoms, such as titanium (Ti), onto a back surface of a silicon (Si) wafer. After deposition, high tensile stresses may result in the thin film causing delamination.

### BRIEF DESCRIPTION OF THE DRAWINGS

The claimed subject matter will be understood more fully from the detailed description given below and from the accompanying drawings of disclosed embodiments which, however, should not be taken to limit the claimed subject matter to the specific embodiment(s) described, but are for explanation and understanding only.

FIG. 1 is a schematic of conventional backside metallization deposition on a wafer.

FIG. 2 is a schematic of backside metallization deposition on a wafer according to one embodiment.

FIG. 3 is a schematic of backside metallization deposition according to one embodiment, after the wafer is released.

FIG. 4 is a schematic of a backside metallization environment according to one embodiment.

FIG. 5 shows a flowchart of a backside metallization method according to one embodiment.

### DETAILED DESCRIPTION

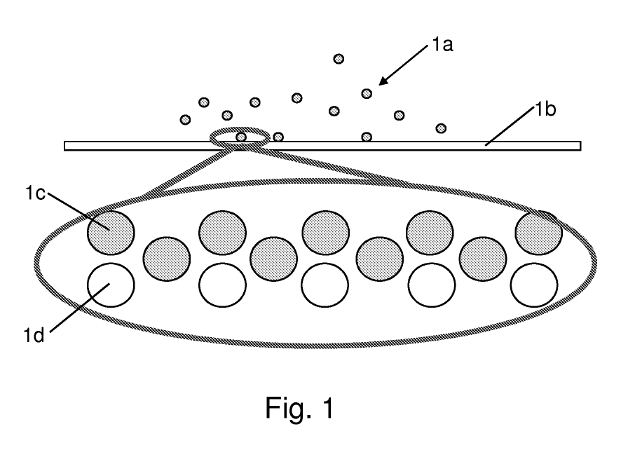

Referring to FIG. 1, during conventional backside metallization (BSM) deposition (also referred to as “flat wafer deposition”) as shown in the schematic, a plurality of titanium (Ti) atoms 1a are deposited on a backside of a silicon (Si) wafer 1b creating a thin film. The BSM process naturally deposits the thin film with a tensile stress because the Ti atoms attempt to line up with the Si atoms during deposition. Since the atomic spacing of the Ti atoms (a=2.95 Å) is smaller than the Si atoms (a=5.43 Å), the result is a tensile stress because the Ti atoms are pulled apart leaving a gap between adjoining Ti atoms. This is apparent in the high magnification region in FIG. 1 showing the exemplary location of Ti atoms 1c located on top of the Si atoms 1d of the wafer. (The figures herein are not drawn to scale.)

When the thin film is normally deposited and sets in flat wafer deposition, it causes a large tensile stress within the thin film. As a result, the wafer is more susceptible to die warpage and BSM delamination at the Die Prep Saw, Tape Reel Die Sort (TRDS), and Chip Attach Module (CAM) Deflux steps in the production process.

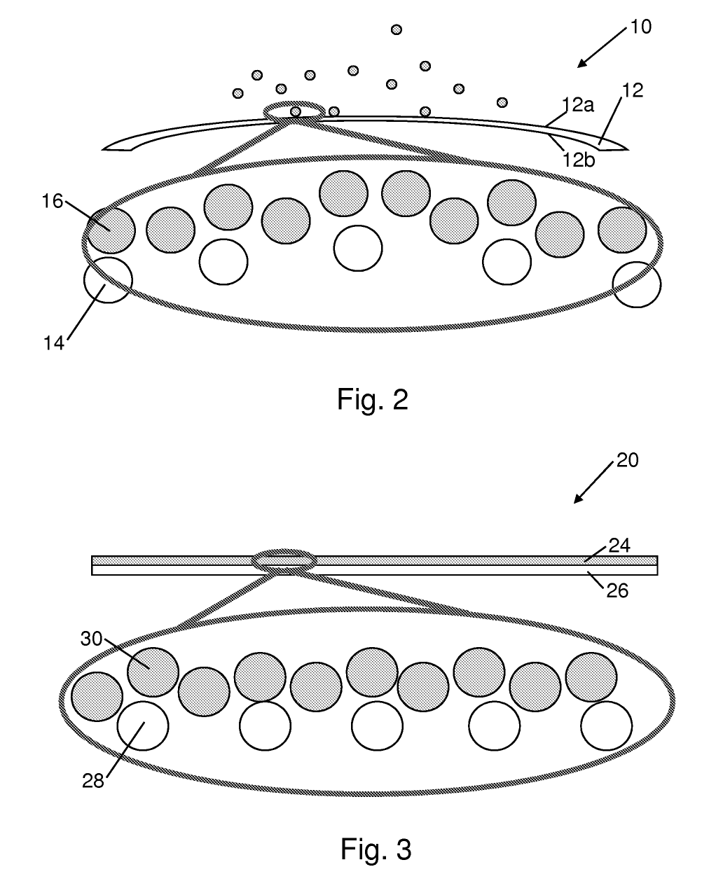

FIG. 2 shows a schematic 10 of a silicon wafer 12 that is bent for BSM according to one embodiment. By bending the wafer so that the back surface 12a is in tension and the front surface 12b is in compression, Si atoms 14 on the back surface are spread further apart from each other as shown in the magnification in the figure. This provides more space between adjacent Si atoms during deposition, especially compared to the original spacing during flat wafer deposition. The Ti atoms 16 are deposited and land at a normal spacing (same spacing that they would fall within during flat wafer deposition) on top of the Si atoms on the wafer.

FIG. 3 shows a schematic 20 of a silicon wafer 22 that was bent for BSM deposition (such as illustrated in FIG. 2) and then released from bending, according to one embodiment. A layer of Ti atoms 24 has been formed on the backside of a Si wafer 26. The wafer is relaxed (returned to flat position after deposition), also referred to as “released”. The Si atoms 28 have returned to their original spacing and/or position with the Ti atoms 30 attached. As a result, the Ti atoms will have less spacing than when the wafer was bent and also less spacing than the original flat wafer deposition. The gaps between the Ti atoms are a lot smaller and the Ti atoms are more densely packed than those in flat wafer deposition, allowing for less tensile stress within the thin film. With less spacing between Ti atoms, there exists less tension.

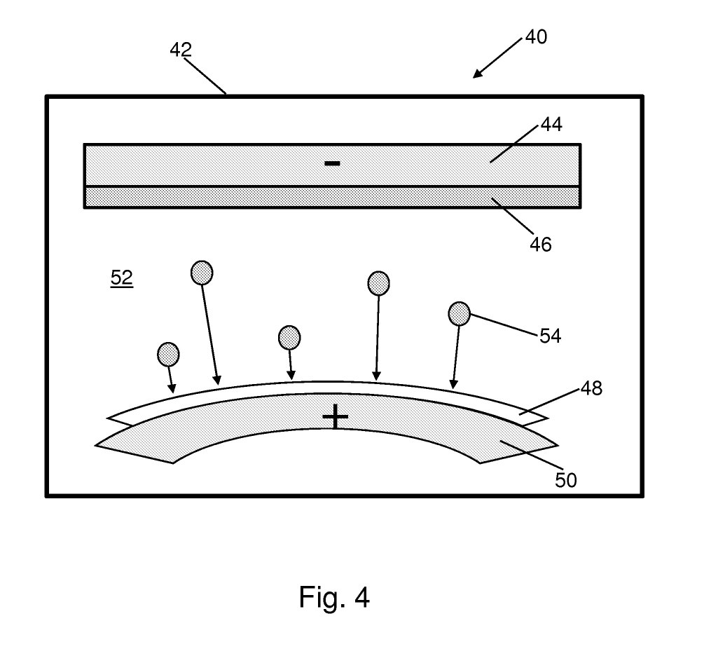

Referring to FIG. 4, a simplified schematic of a backside metallization environment according to one embodiment is shown at 40. The BSM environment includes a pressure vessel 42 (also referred to as “chamber”) creating a low pressure environment. A cathode 44 coupled to target material 46 is placed above a wafer 48 positioned on a domed chuck 50. High voltages are applied to the target material 46 and the chuck 50. The vacuum chamber is filled with an inert gas, such as Argon. The high voltages and low pressure create plasma vapor 52 where atoms break up into their individual elements such as gas ions, free electrons, etc. When the plasma vapor ignites, the target material breaks off into particles of target material 54 for deposition onto the wafer.

By using a domed chuck to mount the wafer and create convex bend in the wafer, the backside of the wafer will undergo tension, and the front (active) side of the wafer will undergo compression. This will allow the Si atoms on the backside of the wafer to spread further apart during target material deposition and when the wafer is relaxed after deposition, the Si atoms will return to their normal spacing and the tensile stress in the thin film will be decreased.

As an example of a mechanism creating bend, the wafer may be held over a dome shaped table with up to a 15 μm center height. A vacuum from the chuck table makes the wafer conform to the dome shaped surface, thus forcing the wafer to hold a convex position as shown. It should be noted that any mechanism may be used to create tension in the back surface of the wafer. Non-limiting examples include dome shaped table, chuck, or other suitable tools. A chuck may be any shape and not necessarily domed, and any dimensions, as long as it increases the spacing between atoms on the surface of the wafer without damage to the wafer.

Further, wafer 48 may be fastened to the chuck 50 by a ring clip (not shown). This is simply a ring that touches the wafer perimeter and holds it down to the chuck. Other mechanisms devised to hold the wafer such as an “E chuck” or electrostatic chucks, etc. may be used.

Although reference has only been made to backside metallization, it is understood that the embodiment(s) disclosed may also apply to front side application of a second substance onto a wafer of a first substance.

Further, the scope of the embodiment(s) is not limited to Si and Ti applications, but may include other suitable materials/substances. For example, the wafer may be made of another semiconductor. Other thin films deposited on the backside of the wafer for BSM may include nickel-vanadium (NiV), gold (Au), and other suitable substances. In addition, one embodiment may include multiple layers of deposition of thin films corresponding to desired thicknesses.

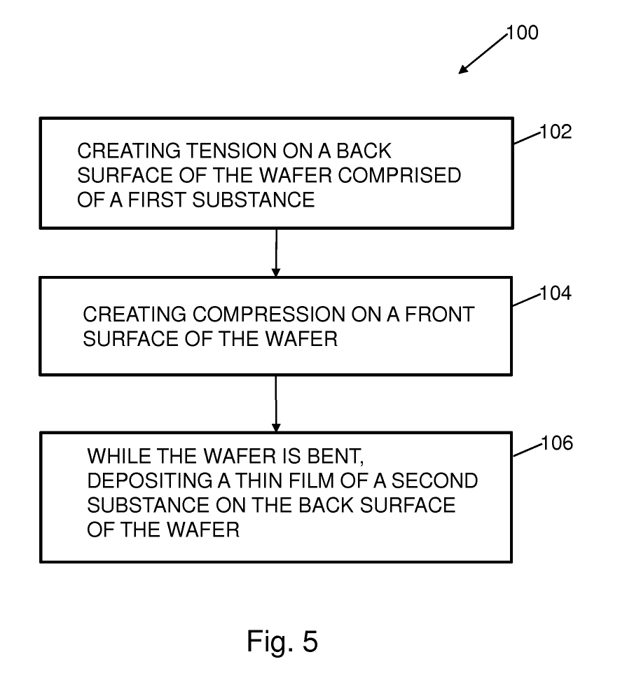

Referring to FIG. 5, according to one embodiment, a method for BSM is disclosed at 100. The method includes, at step 102, creating tension on a back surface of the wafer comprised of a first substance and, at step 104, creating compression on a front surface of the wafer. By creating tension on the back surface and creating compression on the front surface, method 100 causes the wafer to bend into a predetermined shape. While the wafer is bent, the method further includes depositing a thin film of a second substance on the back surface of the wafer at step 106.

In the method, the predetermined shape may be determined by a chuck, which may be dome-shaped. The method may position the wafer on a chuck to create tension and compression. The tension on the back surface of the wafer provides additional space between adjacent atoms on the back surface of the wafer. The method may use a silicon wafer and a titanium target material for deposition, both silicon and titanium having different atomic spacing. Other substances may be used for the deposition process.

According to the method, after releasing the wafer after deposition of the thin film, the atoms of the first substance return to their original spacing before bending of the wafer. The atoms of the second substance have less spacing between them than if the thin film had been deposited without bending of the wafer.

It is appreciated that a method and apparatus to decrease thin film tensile stresses resulting from physical vapor deposition has been explained with reference to one general exemplary embodiment, and that the disclosed subject matter is not limited to the specific details given above. References in the specification made to other embodiments fall within the scope of the claimed subject matter.

Reference in the specification to “an embodiment,” “one embodiment,” “some embodiments,” or “other embodiments” means that a particular feature, structure, or characteristic described in connection with the embodiments is included in at least some embodiments, but not necessarily all embodiments, of the claimed subject matter. The various appearances of “an embodiment,” “one embodiment,” or “some embodiments” are not necessarily all referring to the same embodiments.

If the specification states a component, feature, structure, or characteristic “may”, “might”, or “could” be included, that particular component, feature, structure, or characteristic is not required to be included. If the specification or claim refers to “a” or “an” element, that does not mean there is only one of the element. If the specification or claims refer to “an additional” element, that does not preclude there being more than one of the additional element.

Those skilled in the art having the benefit of this disclosure will appreciate that many other variations from the foregoing description and drawings may be made within the scope of the claimed subject matter. Indeed, the invention is not limited to the details described above. Rather, it is the following claims including any amendments thereto that define such scope and variations.

What is claimed is:

1. A method for depositing a thin film on a wafer, the method comprising: bending the wafer to create tension on a back surface of the wafer and compression on a front surface of the wafer, the wafer comprised of a first substance; and
while the wafer is bent, depositing a thin film of a second substance on the back surface of the wafer.

2. The method of claim 1 wherein the wafer is bent into a predetermined shape.

3. The method of claim 2 wherein the predetermined shape is determined by a chuck.

4. The method of claim 3 wherein the chuck is substantially dome-shaped.

5. The method of claim 1 wherein bending the wafer comprises positioning the wafer on a chuck.

6. The method of claim 1 wherein the tension on the back surface of the wafer provides additional space between adjacent atoms on the back surface of the wafer.

7. The method of claim 1 wherein the first substance and the second substance have different atomic spacing.

8. The method of claim 7 wherein the first substance is silicon and the second substance is titanium.

9. The method of claim 1 further comprising releasing the wafer after deposition of the thin film, wherein atoms of the first substance return to their original spacing before bending of the wafer, and wherein atoms of the second substance have less spacing between them than if the thin film had been deposited without bending of the wafer.

10. A backside metallization deposition apparatus comprising:
a chamber holding a plasma vapor with particles of a first substance for deposition onto a wafer comprised of a second substance; and
a mechanism capable of bending the wafer during deposition;
wherein the mechanism comprises a predetermined shape capable of creating tension on a backside of the wafer, the tension providing more space between adjacent atoms of the second substance on the backside of the wafer, and creating compression on a front side of the wafer.

11. The apparatus of claim 10 wherein the predetermined shape is a dome.

12. The apparatus of claim 10 wherein pressure inside the chamber is low.

13. The apparatus of claim 10 wherein high voltages are applied to the mechanism.

14. The apparatus of claim 10 wherein particles of the first substance adhere to the backside of the wafer during deposition.

15. The apparatus of claim 14 wherein after deposition and the wafer is released from the mechanism, the particles of the first substance deposited on the backside of the wafer are closer together than they were when they were first deposited.

16. The apparatus of claim 15 wherein there is low tensile stresses between the particles of the first substance.
